(19) United States
(12) Patent Application Publication
(10) Pub. No.: US 2024/0377478 A1
(43) Pub. Date: Nov. 14, 2024

(54) APPARATUS AND METHOD FOR MEASURING CONTACT RESISTANCE

(71) Applicant: Keithley Instruments, LLC, Solon, OH (US)

(72) Inventor: Martin J. Rice, Sagamore Hills, OH (US)

(21) Appl. No.: 18/648,130

(22) Filed: Apr. 26, 2024

Related U.S. Application Data
(60) Provisional application No. 63/464,816, filed on May 8, 2023.

(51) Int. Cl. G01R 31/68

(52) U.S. Cl. CPC G01R 31/68

(57) ABSTRACT

A test and measurement instrument includes a first contact check circuit including a first contact check current source isolated from power supplies in the test and measurement instrument. The first contact check current source supplies a first contact check current to a first contact resistance across a first force and first sense nodes that is present in first electrical connections between each of the first force node and first sense node and a first contact node of a DUT. A first voltage detection circuit coupled to the first source and first sense nodes detects a first contact check voltage across the first contact resistance in response to the first contact check current, the voltage indicating a fault in the first electrical connections. A second contact check circuit may be used to detect a fault in a second electrical connection to a second contact node of the DUT.

### CROSS-REFERENCE TO RELATED APPLICATIONS

This disclosure is a non-provisional of and claims benefit from U.S. Provisional Application No. 63/464,816, titled “APPARATUS AND METHOD FOR MEASURING CONTACT RESISTANCE,” filed on May 8, 2023, the disclosure of which is incorporated herein by reference in its entirety.

### TECHNICAL FIELD

This disclosure relates generally to test and measurement (T&M) instruments, and more particularly to techniques for checking electrical connections between a test and measurement instrument and a device under test (DUT).

### BACKGROUND

Whenever a device under test (DUT) is being electrically connected to a test and measurement (T&M) instrument for testing, a need arises for verifying proper electrical connection between the T&M instrument and DUT. In testing a DUT, the T&M instrument is electrically connected to the DUT to supply a voltage or current signal and measure or sense signals generated across the DUT in response to the supplied voltage or current signal. Verifying proper electrical connection between the T&M instrument and DUT is referred to as “contact check” or “performing contact check” in the present description. An improper electrical connection may not only result in erroneous measurements by the T&M instrument, but may also result in damage to the DUT. Damage may occur because feedback of signals generated across the DUT is utilized by the T&M instrument to control the voltage or current signal being supplied, and an improper electrical connection may result in improper feedback, resulting in the T&M instrument supplying a signal that damages the DUT.

Some techniques for performing contact check are prone to error due to unwanted electrical return paths between the T&M instrument and DUT that are present for a contact check signal supplied by the T&M instrument to test the electrical connection. These unwanted return paths may result in erroneous measurements by the T&M instrument when performing contact check. Furthermore, an improper electrical connection may result in the T&M instrument supplying a contact check signal to the DUT having a magnitude of voltage or current that damages the DUT. Accordingly, there is a need for improved techniques for performing contact checks between T&M instruments and DUTs.

### BRIEF DESCRIPTION OF ACCOMPANYING DRAWINGS

FIG. 1 illustrates a test and measurement system including a T&M instrument including contact checking circuitry for detecting faults in an electrical connection between the T&M instrument and a DUT in accordance with some embodiments of the disclosure.

FIG. 2 illustrates a test and measurement system including a source measure unit (SMU) containing contact checking circuitry for detecting faults an electrical connection between the instrument and a DUT in accordance with some embodiments of the disclosure.

FIG. 3 is a more detailed schematic of the contact check circuit of FIG. 1 in accordance with some embodiments of the disclosure.

FIG. 4 is a flowchart of a process of detecting a contact fault in a first electrical connection path between a test and measurement instrument and a first contact node of DUT.

### DETAILED DESCRIPTION

Embodiments of the disclosure are directed to methods of performing contact check of an electrical connection between a test and measurement (T&M) instrument and a device under test (DUT), and to systems for implementing these methods in accordance with some embodiments of the disclosure. In accordance with some embodiments, a test and measurement instrument includes a first contact check circuit including a first contact check current source that is galvanically isolated from one or more power supplies in the test and measurement instrument. Galvanic isolation means the first contact check current source is physically isolated from the one or more power supplies of the test and measurement instrument so that there is no physical or direct conduction path for a first contact check current generated by the first contact check current source to flow to the one or more power supplies. The galvanic isolation eliminates potential inadvertent current return paths for contact check currents supplied by the test and measurement instrument to check connections or contacts to a DUT being tested. These inadvertent current return paths may result in inaccurate contact check of the DUT as well as potential damage to the DUT.

The first contact check current source is coupled between a first force node and a first sense node of the test and measurement instrument, which may be a source measure unit (SMU) in some embodiments. The first contact check current source supplies the first contact check current to a first contact resistance across the first force node and first sense node, where the first contact resistance is present in or results from a first electrical connection path including a first electrical connection between the first force node and a first contact node of a DUT and a second electrical connection between the first sense node and the first contact. A first voltage detection circuit detects a first contact check voltage across the first contact resistance in response to the first contact check current. The first contact check voltage has a value indicating whether a contact fault is present in the first electrical connection path.

In some embodiments, the first contact check circuit includes a limiting resistance coupled across the first force node and first sense node to limit a voltage that may be generated across these two nodes. In this way, the limiting resistance also limits a maximum voltage that may be generated on the first contact node of the DUT and protects the DUT from damage that may result from an excessive voltage on the first contact node. The first contact check circuit must also be capable of use in applications where the value of the first contact resistance can vary widely, and can depend, at least in part, on components used in forming the first electrical connection path. As a result, values of the detected first contact check voltage may vary widely, and may be very small when the first contact resistance has a very small value. Accordingly, in some embodiments the first voltage detection circuit is a variable gain amplifier or other suitable circuit having a programmable gain that may be adjusted to increase the value of the detected first contact check voltage for subsequent processing to determine whether a fault is present in the first electrical connection path.

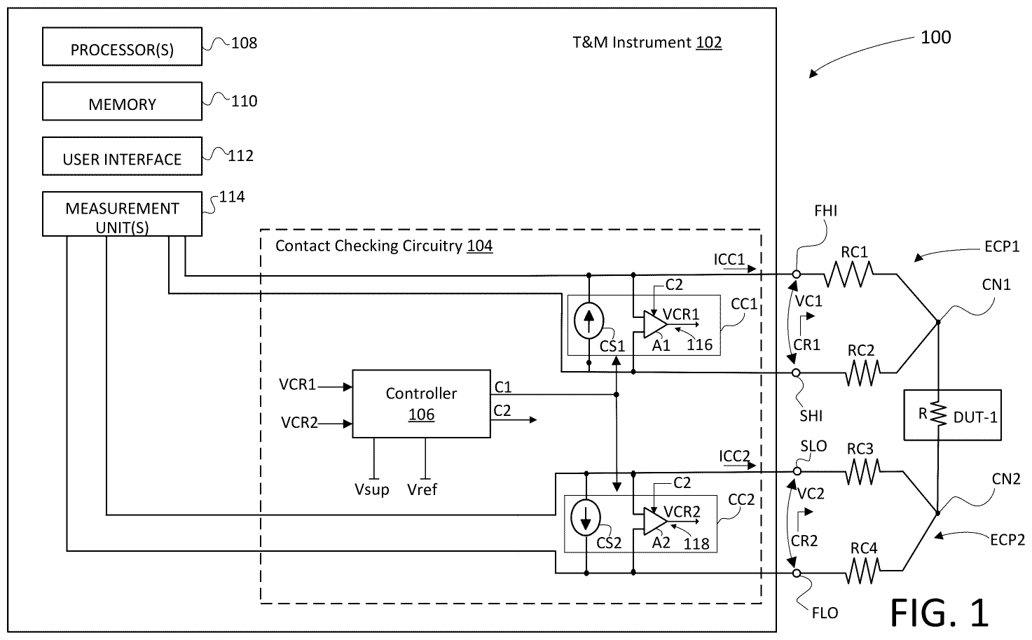

FIG. 1 illustrates a test and measurement system 100 including a T&M instrument 102 including contact checking circuitry 104 to perform contact check of first and second electrical connections paths ECP1, ECP2 between the T&M instrument and a DUT-1 in accordance with some embodiments of the disclosure. In operation, a controller 106 of the contact checking circuitry 104 controls first and second contact check circuits CC1, CC2, which supply galvanically isolated contact check currents ICC1, ICC2 to the first and second electrical connection paths ECP1, ECP2 and measure first and second contact check voltages VC1, VC2 generated across the first and second electrical paths ECP1, ECP2 in response to the galvanically isolated contact check currents ICC1, ICC2. The controller 106 then determines, based on the measured first and second contact check voltages VC1, VC2, whether there is a contact fault or improper connection in either of the first and second electrical connection paths ECP1, ECP2 between the T&M instrument 102 and the DUT-1, as explained in more detail below. The contact checking circuitry 104 enables the T&M instrument 102 to perform contact check on the DUT-1 to ensure the DUT-1 is properly connected to the T&M instrument 102 prior to the T&M instrument applying actual test signals to the DUT-1 for testing. As previously mentioned, a contact fault in the either of the first and second electrical connections paths ECP1, ECP2 may result not only in erroneous test results being received by the T&M instrument 102, but may also cause damage to the DUT-1 when the actual test signals are applied to the DUT-1.

The T&M instrument 102 further includes one or more main processors 108 that may be configured to execute instructions from main memory 110 and may perform any methods and/or associated steps indicated by such instructions. A user interface 112 is coupled to the one or more processors 108 and may include, for example, a keyboard, mouse, touchscreen, output display, file storage, and/or any other controls employable by a user to interact with the test and measurement instrument 102. In some embodiments the user interface 112 may be connected to or controlled by a remote interface (not illustrated), so that a user may control operation of the instrument 102 in a remote location physically away from the instrument. A display portion of the user interface 112 may be a digital screen such as a liquid crystal display (LCD), or any other monitor to display waveforms, measurements, and other data to a user. In some embodiments, the main output display of the user interface 112 may also be located remote from the instrument 102.

One or more measurement units 114 perform the functions of measuring parameters and other qualities of signals from DUTs as measured and being tested by the T&M instrument 102. Typical measurements include measuring voltage, current, and power of input signals in the time domain, as well as measuring features of the signals in the frequency domain. The measurement units 114 represent any measurements that are typically performed on T&M instruments, and the contact checking circuitry 104, or any component thereof like the controller 106, may be integrated within or coupled to such measurement units 114.

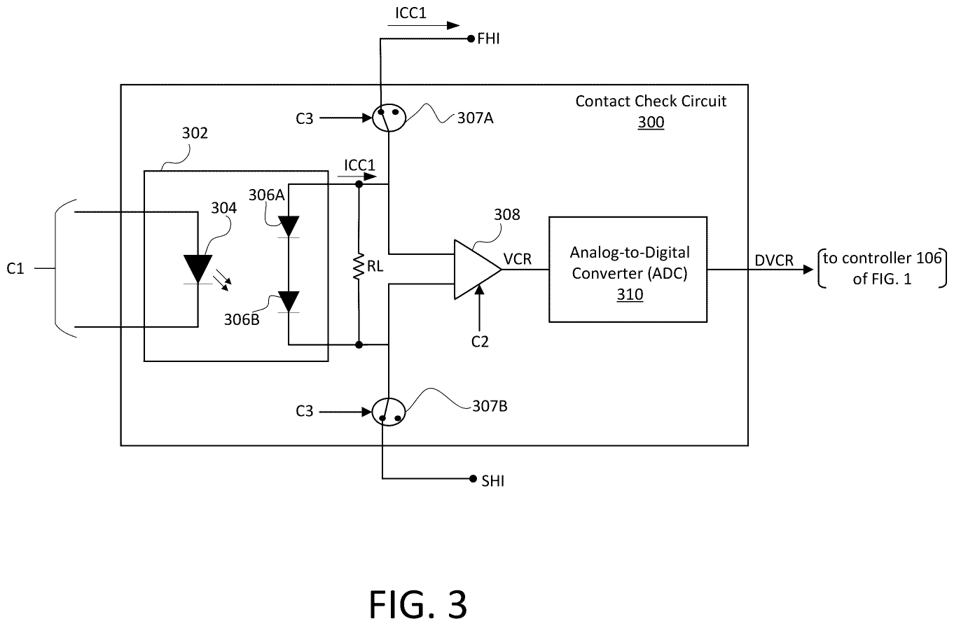

In the contact checking circuitry 104 of FIG. 1, the first contact check circuit CC1 includes a first contact check current source CS1 that is galvanically isolated from one or more power supplies Vsup, Vref in the T&M instrument 102. The galvanic isolation between the first contact check current source CS1 and the power supplies Vsup, Vref of the T&M instrument 102 is described in more detail below with reference to FIG. 3. The one or more power supplies Vsup, Vref represent power supplies for all components in the T&M instrument 102 although shown as coupled only to the controller 106 merely to simplify the FIG. 1. The first contact check current source CS1 is coupled between a force high node FHI and a sense high node SHI of the T&M instrument 102. In response to a first control signal C1 applied from the controller 106 to the first contact check circuit CC1, the first contact check current source CS1 supplies a first contact check current ICC1 to a first contact resistance CR1 coupled across the force high node FHI and sense high node SHI. The first contact check circuit CC1 further includes a first voltage detection circuit 116 coupled across the force high node FHI and sense high node SHI to detect a first contact check voltage VC1 generated across the first contact resistance CR1 in response to the first contact check current ICC1. The first contact resistance CR1 corresponds to the total resistance of the first electrical connection path ECP1 that is present across the first high node FHI and sense high node SHI, as will be described in more detail below. The first contact check voltage VC1 has a value indicating contact potential of the first electrical connection path ECP1, which corresponds to the potential across the first contact resistance CR1. In some embodiments, the first contact check voltage VC1 measured or detected by the first voltage detection circuit 116 is supplied to the controller 106. From the first contact check voltage VC1, the controller 106 determines the first contact resistance CR1, which is given by the first contact check voltage VC1 divided by the first contact check current ICC1 supplied by the first contact check current source CS1. From the determined first contact resistance CR1, a user may then determine whether a contact fault is present in the first electrical connection path ECP1.

The second contact check circuit CC2 includes a second contact check current source CS2 that is galvanically isolated from the one or more power supplies Vsup, Vref in the T&M instrument 102. The galvanic isolation between the first contact check current source CS2 and the power supplies Vsup, Vref of the T&M instrument 102 is described in more detail below with reference to FIG. 3. The second contact check current source CS2 is coupled between a force low node FLO and a sense low node SLO of the T&M instrument 102. In response to the first control signal C1 from the controller 106 supplied to the second contact check circuit CC2, the second contact check current source CS2 supplies a second contact check current ICC2 to a second contact resistance CR2 coupled across the force low node FLO and sense low node SLO. The second contact check circuit CC2 further includes a second voltage detection circuit 118 coupled across the force low node FLO and sense low node SLO to detect a second contact check voltage VC2 generated across the second contact resistance CR2 in response to the second contact check current ICC2. The second contact check voltage VC2 indicates whether a contact fault is present in the second electrical connection path ECP2. The same is true of the value of the second contact resistance CR2. In some embodiments, the second contact check voltage VC2 is supplied to the controller 106 and from the second contact check voltage the controller 106 determines the second contact resistance CR2. In the same way as discussed above for the first contact resistance CR1, the second contact resistance CR2 is given by the second contact check voltage VC2 divided by the second contact check current ICC2 supplied by the second contact check current source CS2. From the determined second contact resistance CR2, a user may then determine whether a contact fault is present in the second electrical connection path ECP2.

In the test and measurement system 100, the first electrical connection path ECP1 includes a first electrical connection between the force high node FHI and a first contact node CN1 of the DUT-1 and includes a second electrical connection between the sense high node SHI and the first contact node CN1 of the DUT-1. The first electrical connection is represented as a contact resistance RC1 that corresponds to the resistance of all components, such as suitable cables, probes, and other components, interconnecting the force high node FHI of the T&M instrument 102 and the first contact node CN1 of the DUT-1 being tested. Similarly, the second electrical connection of the electrical connection path ECP1 is represented as a contact resistance RC2 that corresponds to the resistance of all components interconnecting the sense high node SHI of the T&M instrument 102 and the first contact node CN1 of the DUT-1. The first contact resistance CR1 equals (RC1 + RC2).

The second electrical connection path ECP2 similarly includes a first electrical connection between the sense low node SLO and a second contact node CN2 of the DUT-1 and includes a second electrical connection between the force low node FLO and the second contact node CN2 of the DUT-1. The first electrical connection is represented as a contact resistance RC3 that corresponds to the resistance of all components interconnecting the sense low node SLO of the T&M instrument 102 and the second contact node CN2 of the DUT-1 being tested. Similarly, the second electrical connection of the electrical connection path ECP2 is represented as a contact resistance RC4 that corresponds to the resistance of all components interconnecting the force low node FLO of the T&M instrument 102 and the second contact node CN2 of the DUT-1. The second contract resistance CR2 is equal to (RC3 + RC4).

The force high node FHI and sense high node SHI associated with the contact check circuit CC1 and electrical connection path ECP1 may be referred to as a first pair of check nodes <FHI, SHI> in the present description. Similarly, the force low node FLO and sense low node SLO associated with the contact check circuit CC2 and electrical connection path ECP2 may be referred to as a second pair of check nodes <FLO, SLO>. The force high node FHI and force low node FLO may also be referred to as first and second force nodes, respectively, and the sense high node SHI and sense low node SLO referred to as first and second sense nodes.

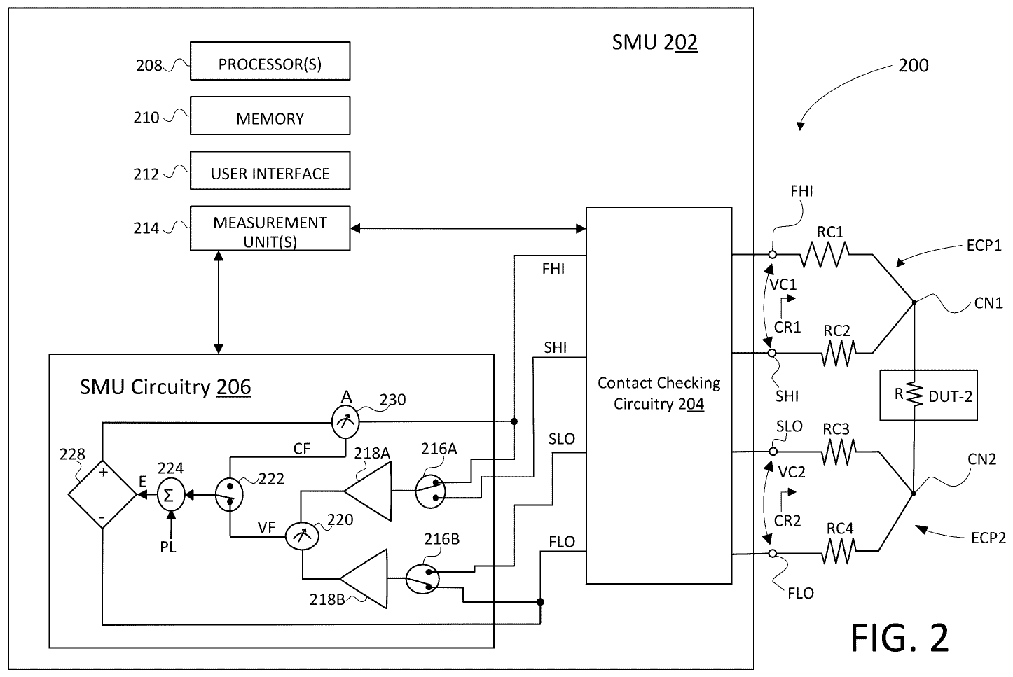

As seen in FIG. 1, each of the pairs of check nodes <FHI, SHI> and <FLO, SLO> are also coupled directly to the one or more measurement units 114. Once the contact checking circuitry 104 has completed performing contact check for a DUT-1 coupled to the T&M instrument 102, the contact checking circuitry 104 is turned OFF or deactivated to isolate the contact checking circuitry 104 from the pairs of check nodes <FHI, SHI> and <FLO, SLO>. This functionality is not expressly illustrated in FIG. 1 but is described in more detail below with reference to FIG. 3. During normal operation of the T&M instrument 102, the contact checking circuitry 104 is isolated from the pairs of check nodes <FHI, SHI> and <FLO, SLO>, and the one or more measurement units 114 apply and sense signals on the check nodes <FHI, SHI> and <FLO, SLO> to test DUTs coupled to these nodes. In some embodiments of the disclosure, the T&M instrument 102 is an SMU or a power supply instrument. The T&M instrument 102 may be other types of instruments as well. An embodiment of a T&M system in which the instrument is an SMU is described in more detail below with reference to FIG. 2. In the embodiment of FIG. 1, each of the voltage detection circuits 116, 118 is a differential amplifier A1, A2 having inputs coupled across the corresponding pair of check nodes <FHI, SHI> and <FLO, SLO>, respectively. Each differential amplifier A1, A2 amplifies the contact check voltage VC1, VC2 to generate a corresponding contact resistance voltage VCR1, VCR2, which is supplied to the controller 106. Each contact resistance voltage VCR1, VCR2 depends on or is a function of the contact resistance CR1, CR2 between the associated pair of check nodes <FHI, SHI>, <FLO, SLO>.

A gain of each programmable amplifier A1, A2 is programmable and has a value that is adjustable in response to a second control signal C2 provided by the controller 106. In some embodiments, the programmable gain of each amplifier A1, A2 is set, through the control signal C2, to one of 1, 10, 100, and 1000. In this way, the controller 106 may generate the control signal C2 to control the value of the programmable gain of each amplifier A1, A2 to provide a wide dynamic range for the contact check voltages VC1, VC2 being amplified. In some applications of the contact checking circuitry 104, the measuring of contact resistances CR1, CR2 as low as 1 Ohm or less is desirable. For this reason, a high gain of 1000 for each amplifier A1, A2 enables the amplifier to amplify a very small voltage contact check voltage VC1, VC2 generated across the corresponding contact resistance CR1, CR2 to a measurable level for the generated contact resistance voltage VCR1, VCR2. In some embodiments, the second control signal C2 includes two independent gain signals, one gain signal being applied to each of the programmable amplifiers A1, A2. In this way, the controller 106 may independently adjust the value of the gain signals to program the gains of the programmable amplifiers A1, A2 to different values.

In one embodiment of the contact check circuits CC1, CC2, each of the contact check current sources CS1, CS2 supplies a contact check current ICC1, ICC2 of 30 microamps (uA), resulting in contact check voltages VC1, VC2 that vary only 30 microvolts (uV) per Ohm variation of contact resistance CR1, CR2. In this situation, the controller 106 supplies the second control signal C2 to set the gain of the amplifiers A1, A2 to 1000, resulting in the amplifiers generating contact resistance voltages VCR1, VCR2 that vary at a rate of 30 mV per Ohm of contact resistance CR1, CR2. When the contact resistances CR1, CR2 are larger, such as due to larger lead resistances in the form of cabling and probe contacts, the resulting contact check voltages VC1, VC2 are larger. In this situation, the controller 106 generates the control signal C2 to decrease the gain of the amplifiers A1, A2. This variation in gain of the amplifiers A1, A2 gives the contact checking circuitry 104 a useful range of contact resistances CR1, CR2 that may be sensed or detected of approximately 0 Ohms to 37 kOhms, with a resolution of 0.1 Ohms in some embodiments of the disclosure.

The utilization of contact check currents ICC1, ICC2 having the small value of 30 uA in the embodiment of the contact check circuits CC1, CC2 being described has the advantage of protecting the DUT-1 from damage during testing. This low level 30 uA current for the contact check currents ICC1, ICC2 limits the current that can be supplied to the DUT-1 in the event of a miswiring or improper connection between the T&M instrument 102 and the DUT-1. For example, when connection of the force node FHI and force low node FLO of the T&M instrument 102 are reversed and the DUT-1 is placed in series with one of the contact check current sources CS1, CS2, only the low level 30 uA current for the contact check current ICC1, ICC2 would flow through the DUT-1.

In one embodiment, the controller 106 further executes a calibration process to establish the desired gain to be utilized during testing of a particular DUT-1. The calibration process includes coupling one or more known load resistances between each of pairs of check nodes <FHI, SHI>, <FLO, SLO> of the test and measurement instrument 102. For each known load resistance, the controller 106 applies the control signal C1 to activate the current sources CS1, CS2 and then measures the corresponding contact resistance voltages VCR1, VCR2 generated by the amplifiers A1, A2 for different gain values of the amplifiers A1, A2, where the controller 106 controls the gain through the control signal C2. The controller 106 then selects a gain value that provides a contact resistance voltage VCR1, VCR2 having a suitable level for subsequent processing by the controller 106 in performing contact check of the first and second electrical connection paths ECP1, ECP2. The value of the control signal C2 to cause each amplifier A1, A2 to provide the desired gain may then be stored by the controller 106 in non-volatile memory in the controller 106, or in main memory 110 of the test and measurement instrument 102.

In addition to gain, the calibration process may also include calibration to compensate for any offsets that may be present in the contact check circuits CC1, CC2. For example, where a zero voltage is present across the pairs of the check nodes <FHI, SHI>, <FLO, SLO> each of the amplifiers A1, A2 ideally outputs a zero level for the contact resistance voltage VCR1, VCR2, but may instead outputs a non-zero level due to offsets amplifiers. In some embodiments, the controller 106 also compensates for such offsets during the calibration process, also storing an offset value for each amplifier A1, A2 along with the desired gain in non-volatile memory in the controller 106 or in main memory 110 of the test and measurement instrument 102. The controller 106 can be activated to execute the calibration process periodically to maintain proper calibration of the T&M instrument 102.

Although the contact checking circuitry 104 includes the two contact check circuits CC1, CC2 in the embodiment of FIG. 1, in some embodiments the contact checking circuitry 104 may include only a single contact check circuit to test connection to a single contact node of a DUT. This single-ended configuration of the contact checking circuitry 104 may be useful for single-ended test configurations of the DUT-1 where one contact node of the DUT-1 is connected to a reference voltage (e.g., ground) of the test and measurement instrument 102 and the other contact node is connected through an electrical connection path to the corresponding check nodes of the single contact check circuit. The contact checking circuitry 104 of FIG. 1 may also be utilized in such single-ended test configurations with only one of the two contact check circuits CC1, CC2 being utilized to test an electrical connection path to one of the contact nodes of the DUT-1.

FIG. 2 illustrates a test and measurement system 200 including a source measure unit (SMU) 202 containing contact checking circuitry 204 to perform contact check of first and second electrical connections paths ECP1, ECP2 between the SMU 202 and a DUT-2 in accordance with some embodiments of the disclosure. In the test and measurement system 200, the contact checking circuitry 204 corresponds to the contact checking circuitry 104 of FIG. 1, and therefore the above disclosure of contact checking circuitry 104 applies to the contact checking circuitry 204. The SMU 202 includes SMU circuitry 206 that is coupled through the contact checking circuitry 204 to pairs of check nodes <FHI, SHI>, <FLO, SLO> of the SMU. The SMU 202 includes one or more main processors 208, a main memory 210, user interface 212, and one or more measurement units 214 that operate in the same way or a similar way as the corresponding components 108-114 of FIG. 1, and thus the above disclosure of components 108-114 applies to components 208-214 of FIG. 2.

The SMU circuitry 206 includes circuitry to supply a current through or a voltage across the force nodes FHI, FLO and to sense or measure a voltage across the contact nodes CN1, CN2 of the DUT-2 during normal operation of the SMU 202 after the contact checking circuitry 204 has performed a contact check. In operation, the SMU circuitry 206 operates in either a local sense mode or a remote sense mode. When operating in the local sense mode, two switches 216A, 216B in the SMU circuitry 206 are set in the positions shown in FIG. 2, coupling force nodes FHI, FLO to inputs of feedback amplifiers 218A, 218B. Only the two source or force nodes FHI, FLO are utilized to drive a signal from the SMU circuitry 206 at the force nodes FHI, FLO and to sense this signal at the force nodes FHI, FLO. Thus, in the local sense mode, the sensing of the signal being driven or provided by the SMU circuitry 206 across the force nodes FHI, FLO is sensed as well directly at the force nodes FHI, FLO of the SMU 202.

In the local sense mode, the feedback amplifiers 218A, 218B provide outputs indicating the voltage across the force nodes FHI, FLO to a voltage detection circuit 220 that generates a feedback voltage signal VF indicating this voltage. The voltage signal VF is supplied to a first input of a summation circuit 224 that receives a programmable level signal PL indicating a desired value or level for the feedback voltage signal VF. The summation circuit 224 generates an error signal E indicating the difference between the VF and PL signals and this error signal E is supplied to adjust or control a voltage being supplied by programmable voltage source 228, which is coupled across the force nodes FHI, FLO. In this way, the SMU circuitry 206 provides a desired voltage, as indicated by the programmable level signal PL, across the force nodes FHI, FLO to the DUT-2 being tested. The prior operation describes a first voltage mode of operation of the SMU circuitry 202, and the SMU circuitry 202 operates in this first mode when the position of the switch 222 is as shown in FIG. 2.

The SMU circuitry 202 further includes a current sensor 230 coupled between the programmable voltage source 228 and the force high node FHI to supply a desired current to the DUT-2 being tested. The current sensor 230 senses the current being supplied by the programmable voltage source 228 and provides a feedback current signal CF indicating the current being supplied through the switch 222 to the first input of the summation circuit 224. The switch 222 is in the opposite position of that shown in FIG. 2 in this second mode of operation to couple the output of the current sensor 230 to the first input of the summation circuit 224. In this second mode of operation, the programmable level signal PL indicates a desired level for the feedback current signal CF, and generates the error signal E to adjust the value of the programmable voltage source 228 so that the desired current, as sensed by the current sensor 230, is supplied by the SMU circuitry 206 to the DUT-2 being tested.

When operating in the remote sense mode, the two switches 216A, 216B in the SMU circuitry 206 are set in the opposite positions shown in FIG. 2, namely coupling the sense nodes SHI, SLO to inputs of the feedback amplifiers 218A, 218B. In this way, the voltage across the contact nodes CN1, CN2 of the DUT-2 is supplied by the feedback amplifiers 218A, 218B to the voltage detection circuit 220, which generates the feedback voltage signal VF indicating this remotely sensed voltage across the contact nodes CN1, CN2. In the remote sense mode, the SMU circuitry 206 operates in same way as just described for the local sense mode except that the feedback voltage signal VF is sensed directly at the contact nodes CN1, CN2 of the DUT-2 instead of being sensed at the force nodes FHI, FLO of the SMU 202. During the remote sense mode, the SMU circuitry 206 places itself in a state so that the SMU circuitry 206 effectively isolates itself from the pairs of check nodes <FHI, SHI>, <FLO, SLO> so that the SMU circuitry 206 does not affect voltages generated on the check nodes <FHI, SHI>, <FLO, SLO> as the contact checking circuitry 204 performs contact check on the DUT-2.

FIG. 3 is a more detailed schematic of a contact check circuit 300 in accordance with some embodiments of the disclosure. The contact check circuit 300 corresponds to one embodiment of the contact check circuit CC1 of FIG. 1. The contact check circuit CC2 can have the same structure as contact check circuit 300 in some embodiments of the contact checking circuitry 104 of FIG. 1. The contact check circuit 300 includes a photovoltaic device 302 (corresponding to contact check current source CS1 in FIG. 1) that receives the first controls signal C1 from the controller 106 (FIG. 1) and generates the first galvanically isolated contact check current ICC1 in response to the first control signal C1. The photovoltaic device 302 provides galvanic isolation for the contact check current ICC1 through optical isolation.

A light emitting diode (LED) 304 receives the first control signal C1 and generates light in response to the first control signal. Series connected photodiodes 306A, 306B in the photovoltaic device 302 generate the contact check current ICC1 in response to the light from the LED 304. In this way, the optical coupling between the LED 304 and photodiodes 306A, 306B provides galvanic isolation between power supplies (e.g., Vsup, Vref in FIG. 1) in the T&M instrument (e.g., T&M instrument 102 in FIG. 1) containing the contact check circuit 300 and the contact check current ICC1 generated by the photovoltaic device 302. As discussed above, this galvanic isolation eliminates possible return paths for the contact check current ICC1 that could result in erroneous contact check for a contact node of a DUT (not shown in FIG. 3) coupled to the force high node FHI and sense high node SHI to which the contact check circuit 300 is coupled.

A limiting resistor RL is coupled across the series connected photodiodes 306A, 306B to limit a maximum voltage that may be developed across the photodiodes and in this way limits a maximum voltage across the check nodes <FHI, SHI>. An anode of the photodiode 306A is coupled through a first isolation switch 307A to the force high node FHI and a cathode of the photodiode 306B is coupled through a second isolation switch 307B to the sense high node SHI. Each of the isolation switches 307A, 307B receives a third control signal C3 that is provided by the controller 106 of FIG. 1 to selectively couple or isolate the contact check circuit 300 from the pair of check nodes <FHI, SHI>. When contact check is being performed on a DUT coupled to a T&M instrument including the contact check circuit 300, the third control signal C3 is applied to put the switches 307A, 307B in the positions shown in FIG. 3 and coupled the contact check circuit 300 to the check nodes <FHI, SHI>. Once the contact check has been completed and during normal operation of the T&M instrument including the contact check circuit 300, the third control signal C3 is applied to the to put the switches 307A, 307B in the opposite position as shown in FIG. 3, isolating the contact check circuit 300 from the check nodes <FHI, SHI>. In one example of the contact check circuit 300, the limiting resistor RL has a value of 50 kOhms and the contact check current ICC1 is 30 uA, which results in a maximum voltage of 1.5 volts across the pair of check nodes <FHI, SHI>.

The contact check circuit 300 further includes an amplifier 308 having inputs coupled across the photodiodes 306A, 306B and which generates a contact resistance voltage VCR indicating the voltage across a contact resistance coupled between the pair of check nodes <FHI, SHI>, which corresponds to the voltage across these check nodes <FHI, SHI>. An analog-to-digital converter (ADC) 310 receives the contact resistance voltage VCR from amplifier 308 and generates a corresponding digital contact resistance voltage DVCR, which can be supplied to controller 106 (FIG. 1) to determine a value of the contact resistance CR1 (not shown in FIG. 3) coupled across the pair of check nodes <FHI, SHI>and, based on this determined value, determine whether a contact fault is present in an electrical connection path (not shown) coupled across the pair of check nodes <FHI, SHI>. The ADC 310 is shown as part of the contact check circuit 300 in the embodiment of FIG. 3, but the ADC 310 may be part of the controller 106 in some embodiments of the disclosure.

The specific structure of the contact check circuit 300 to provide the desired galvanic isolation of the contact check current ICC1 may vary in different embodiments of the disclosure. For example, the structure of the photovoltaic device 302 may vary, and may include multiple LEDs 304 and more or fewer photodiodes 306A, 306B. In some embodiments, a different type of device may be utilized in place of the photovoltaic device 302 to provide the desired galvanic isolation. For example, a suitable transformer may be utilized in place of the photovoltaic device 302 in some embodiments of the contact check circuit 300.

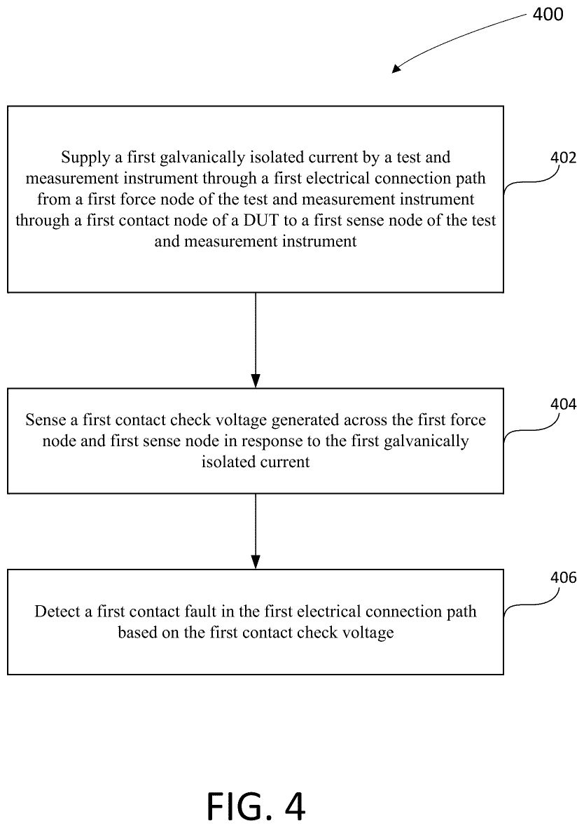

FIG. 4 is a flowchart of a process 400 of detecting a contact fault in a first electrical connection path between a test and measurement instrument and a first contact node of a DUT. The process 400 includes an operation 402 including supplying a first galvanically isolated current by a test and measurement instrument through a first electrical connection path from a first force node of the test and measurement instrument through a first contact node of a DUT to a first sense node of the test and measurement instrument. The first galvanically isolated current is galvanically isolated from one or more power supplies of the test and measurement instrument. From operation 402 the process 400 goes to operation 404 that includes sensing a first contact check voltage generated across the first force node and first sense node in response to the first galvanically isolated current. From operation 404 the process 400 goes to operation 406 that includes detecting a first contact fault in the first electrical connection path based on the first contact check voltage.

In embodiments of the process 400, the operation 406 of detecting the first contact fault includes determining a first contact resistance of the first electrical connection path based on the first contact check voltage and first galvanically isolated current, comparing the determined first contact resistance to a threshold, and determining the first contact fault is present when the determined first contact resistance exceeds the threshold. In some embodiments, the operation 404 further includes limiting a maximum value of the first contact check voltage. Limiting the maximum value of the first contact check voltage includes coupling a resistance across the first force node and the first sense node in some embodiments. In some embodiments, the operation 404 includes amplifying the first contact check voltage by a programmable gain, where the programmable gain has a value selected from the group consisting of 1, 10, 100, and 1000 in some embodiments.

In some embodiments, the process 400 includes detecting a contact fault in a second electrical connection path between the test and measurement instrument and a second contact node of the DUT. In this embodiment, the operation 402 further includes supplying a second galvanically isolated current by the test and measurement instrument through a second electrical connection path from a second force node of the test and measurement instrument through a second contact node of the DUT to a second sense node of the test and measurement instrument. In this embodiment, the operation 404 includes sensing a second contact check voltage generated across the second force node and second sense node in response to the second galvanically isolated current and the operation 406 includes detecting a second contact fault in the second electrical connection path based on the second contact check voltage.

The need for verifying proper connection between a T&M instrument and a DUT arises whenever the DUT is being electrically connected to the T&M instrument for testing. For example, in applications such as wafer testing during semiconductor manufacturing, a wafer probe may include a large number of probe contacts, with the pitch between these probe contacts being very small. The probe contacts have tips that are ideally aligned in a plane to make contact with respective contact pads on a planar surface of a wafer including DUTs being tested. Planar misalignment of the tips of any of the probe contacts may result in the probe contact not making proper physical and thereby electrical contact with a corresponding contact pad on the wafer.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

### EXAMPLES

Illustrative examples of the technologies disclosed herein are provided below. A configuration of the technologies may include any one or more, and any combination of, the examples described below.

Example 1 is a test and measurement instrument, including a first contact check circuit, including a first contact check current source isolated from one or more power supplies in the test and measurement instrument. The first contact check current source is coupled between a first force node and a first sense node of the test and measurement instrument and configured, in response to a first control signal, to supply a first contact check current to a first contact resistance across the first force node and first sense node. The first contact resistance is present in first electrical connections between each of the first force node and the first sense node and a first contact node of a device under test (DUT). A first voltage detection circuit is coupled to the first force node and first sense node, the first voltage detection circuit configured to detect a first contact check voltage across the first contact resistance in response to the first contact check current, the first contact check voltage having a value indicating whether a contact fault is present in the first electrical connections.

Example 2 is the test and measurement instrument of Example 1, wherein the first contact check current source includes an optically isolated current source that is optically isolated from the one or more power supplies of the test and measurement instrument.

Example 3 is the test and measurement instrument of Example 2, wherein the optically isolated current source comprises a photovoltaic isolator.

Example 4 is the test and measurement instrument of Example 1, wherein the first contact check current source comprises an isolation transformer.

Example 5 is the test and measurement instrument of Example 1, wherein the first voltage detection circuit comprises a programmable amplifier having inputs coupled across the first force node and first sense node and configured to generate the first contact check voltage on an output, and the programmable amplifier having a gain that is adjustable in response to a second control signal.

Example 6 is the test and measurement instrument of Example 1, further comprising a first voltage limiting resistance coupled in parallel with the first contact check current source between first force node and the first sense node.

Example 7 is the test and measurement instrument of Example 5, wherein the first contact check circuit further comprises first switching circuitry coupled between the first contact check current source and first voltage detection circuit, the first switching circuitry configured to selectively couple the first contact check current source and first voltage detection circuit to the first force node and first sense node or to isolate the first contact check current source and first voltage detection circuit from the first force node and first sense node.

Example 8 is the test and measurement instrument of Example 1, further comprising a first analog-to-digital converter coupled to the first voltage detection circuit to receive the first contact check voltage and configured to generate a corresponding digital contact check voltage.

Example 9 is the test and measurement instrument of Example 1, further comprising a second contact check circuit, the second contact check circuit including a second contact check current source that is galvanically isolated from the one or more power supplies in the test and measurement instrument, the second contact check current source coupled between a second force node and a second sense node of the test and measurement instrument and configured, in response to the first control signal, to supply a second contact check current to a second contact resistance across the second force node and second sense node, the second contact resistance present in second electrical connections between each of the second force node and second sense node and a second contact node of the DUT, and a second voltage detection circuit coupled to the second force node and second sense node to detect a second contact check voltage across the second contact resistance in response to the second contact check current, the second contact check voltage having a value indicating a fault in the second electrical connections.

Example 10 is the test and measurement instrument of Example 9, further including a controller coupled to the first and second contact check circuits, the controller configured to apply the first control signal to cause the first and second contact check current sources to supply the first and second contact check currents, based on the first and second contact check currents and the first and second contact check voltages, determine values of the first and second contact resistances, and detect faults in the first and second electrical connections based on the determined values of the first and second contact resistances.

Example 11 is the test and measurement instrument of Example 1, wherein the test and measurement instrument is a source measure unit.

Example 12 is a method including supplying a first galvanically isolated current by a test and measurement instrument through a first electrical connection path from a first force node of the test and measurement instrument through a first contact node of a DUT to a first sense node of the test and measurement instrument, the first galvanically isolated current being galvanically isolated from one or more power supplies of the test and measurement instrument; sensing a first contact check voltage generated across the first force node and first sense node in response to the first galvanically isolated current; and detecting a first contact fault in the first electrical connection path based on the first contact check voltage.

Example 13 is the method Example 12, wherein detecting the first contact fault further includes determining a first contact resistance of the first electrical connection path based on the first contact check voltage and first galvanically isolated current; comparing the determined first contact resistance to a threshold; and determining the first contact fault is present when the determined first contact resistance exceeds the threshold.

Example 14 is the method of Example 12, further including limiting a maximum value of the first contact check voltage.

Example 15 is the method of Example 12, wherein limiting a maximum value of the first contact check voltage comprises coupling a resistance across the first force node and the first sense node.

Example 16 is the method of Example 12, further including amplifying the first contact check voltage by a programmable gain.

Example 17 is the method of Example 12, wherein a programmable gain has a value selected from the group consisting of 1, 10, 100, and 1000.

Example 18 is the method of Example 12, further including supplying a second galvanically isolated current by the test and measurement instrument through a second electrical connection path from a second force node of the test and measurement instrument through a second contact node of the DUT to a second sense node of the test and measurement instrument; sensing a second contact check voltage generated across the second force node and second sense node in response to the second galvanically isolated current; and detecting a second contact fault in the second electrical connection path based on the second contact check voltage.

Example 19 is a test and measurement instrument, including a first contact check circuit, including: a first contact check current source coupled between a first force node and a first sense node of the test and measurement instrument, the first contact check current source being galvanically isolated from one or more power supplies in the test and measurement instrument; and a first voltage detection circuit configured to detect a first contact check voltage across the first force node and first sense node; a second contact check circuit, including: a second contact check current source coupled between a second force node and a second sense node of the test and measurement instrument, the second contact check current source being galvanically isolated from the one or more power supplies in the test and measurement instrument; and a second voltage detection circuit configured to detect a second contact check voltage across the second force node and second sense node; a first electrical connection path including a first electrical connection between the first force node and a first contact node of a device under test and a second electrical connection between the first sense node and the first contact node; a second electrical connection path including a first electrical connection between the second force node and a second contact node of the device under test and a second electrical connection between the second sense node and the second contact node; and a controller coupled to the first and second contact check circuits, the controller configured to control the first and second contact check current sources to supply the first and second contact check currents to the first and second electrical connection paths and, based on the first and second contact check currents and first and second contact check voltages detected by the first and second voltage detection circuits, the controller configured to determine first and second contact resistances of the first and second electrical connection paths and to detect faults in the first and second electrical connection paths based on the determined first and second contact resistances.

Example 20 is the test and measurement instrument of Example 19, wherein the test and measurement instrument is a source measure unit (SMU).

The foregoing description has been set forth merely to illustrate example embodiments of disclosure and is not intended to be limiting. Since modifications of the disclosed embodiments incorporating the substance of the invention may occur to person skilled in the art, the invention should be construed to include everything within the scope of the invention.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that all features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Also, when reference is made in this application to a method having two or more defined steps or operations, the defined steps or operations can be carried out in any order or simultaneously, unless the context excludes those possibilities.

Although specific examples of the disclosure have been illustrated and described for purposes of illustration, it will be understood that various modifications may be made without departing from the spirit and scope of the disclosure. Accordingly, the disclosure should not be limited except as by the appended claims.

We claim:

1. A test and measurement instrument, comprising:
a first contact check circuit, including:
a first contact check current source isolated from one or more power supplies in the test and measurement instrument, the first contact check current source coupled between a first force node and a first sense node of the test and measurement instrument and configured, in response to a first control signal, to supply a first contact check current to a first contact resistance across the first force node and first sense node, the first contact resistance present in first electrical connections between each of the first force node and the first sense node and a first contact node of a device under test (DUT); and
a first voltage detection circuit coupled to the first force node and first sense node, the first voltage detection circuit configured to detect a first contact check voltage across the first contact resistance in response to the first contact check current, the first contact check voltage having a value indicating whether a contact fault is present in the first electrical connections.

2. The test and measurement instrument of claim 1, wherein the first contact check current source comprises an optically isolated current source that is optically isolated from the one or more power supplies of the test and measurement instrument.

3. The test and measurement instrument of claim 2, wherein the optically isolated current source comprises a photovoltaic isolator.

4. The test and measurement instrument of claim 1, wherein the first contact check current source comprises an isolation transformer.

5. The test and measurement instrument of claim 1, wherein the first voltage detection circuit comprises a programmable amplifier having inputs coupled across the first force node and first sense node and configured to generate the first contact check voltage on an output, and the programmable amplifier having a gain that is adjustable in response to a second control signal.

6. The test and measurement instrument of claim 1, further comprising a first voltage limiting resistance coupled in parallel with the first contact check current source between first force node and the first sense node.

7. The test and measurement instrument of claim 5, wherein the first contact check circuit further comprises first switching circuitry coupled between the first contact check current source and first voltage detection circuit, the first switching circuitry configured to selectively couple the first contact check current source and first voltage detection circuit to the first force node and first sense node or to isolate the first contact check current source and first voltage detection circuit from the first force node and first sense node.

8. The test and measurement instrument of claim 1, further comprising a first analog-to-digital converter coupled to the first voltage detection circuit to receive the first contact check voltage and configured to generate a corresponding digital contact check voltage.

9. The test and measurement instrument of claim 1, further comprising a second contact check circuit, the second contact check circuit including:
a second contact check current source that is galvanically isolated from the one or more power supplies in the test and measurement instrument, the second contact check current source coupled between a second force node and a second sense node of the test and measurement instrument and configured, in response to the first control signal, to supply a second contact check current to a second contact resistance across the second force node and second sense node, the second contact resistance present in second electrical connections between each of the second force node and second sense node and a second contact node of the DUT; and
a second voltage detection circuit coupled to the second force node and second sense node to detect a second contact check voltage across the second contact resistance in response to the second contact check current, the second contact check voltage having a value indicating a fault in the second electrical connections.

10. The test and measurement instrument of claim 9, further comprising a controller coupled to the first and second contact check circuits, the controller configured to:
apply the first control signal to cause the first and second contact check current sources to supply the first and second contact check currents;
based on the first and second contact check currents and the first and second contact check voltages, determine values of the first and second contact resistances; and
detect faults in the first and second electrical connections based on the determined values of the first and second contact resistances.

11. The test and measurement instrument of claim 1, wherein the test and measurement instrument is a source measure unit.

12. A method, comprising:
supplying a first galvanically isolated current by a test and measurement instrument through a first electrical connection path from a first force node of the test and measurement instrument through a first contact node of a DUT to a first sense node of the test and measurement instrument, the first galvanically isolated current being galvanically isolated from one or more power supplies of the test and measurement instrument;
sensing a first contact check voltage generated across the first force node and first sense node in response to the first galvanically isolated current; and
detecting a first contact fault in the first electrical connection path based on the first contact check voltage.

13. The method of claim 12, wherein detecting the first contact fault further comprises:
determining a first contact resistance of the first electrical connection path based on the first contact check voltage and first galvanically isolated current;
comparing the determined first contact resistance to a threshold; and
determining the first contact fault is present when the determined first contact resistance exceeds the threshold.

14. The method of claim 12, further comprising limiting a maximum value of the first contact check voltage.

15. The method of claim 12, wherein limiting a maximum value of the first contact check voltage comprises coupling a resistance across the first force node and the first sense node.

16. The method of claim 12, further comprising amplifying the first contact check voltage by a programmable gain.

17. The method of claim 12, wherein a programmable gain has a value selected from the group consisting of 1, 10, 100, and 1000.

18. The method of claim 12, further comprising:
supplying a second galvanically isolated current by the test and measurement instrument through a second electrical connection path from a second force node of the test and measurement instrument through a second contact node of the DUT to a second sense node of the test and measurement instrument;
sensing a second contact check voltage generated across the second force node and second sense node in response to the second galvanically isolated current; and
detecting a second contact fault in the second electrical connection path based on the second contact check voltage.

19. A test and measurement instrument, comprising:
a first contact check circuit, including:
a first contact check current source coupled between a first force node and a first sense node of the test and measurement instrument, the first contact check current source being galvanically isolated from one or more power supplies in the test and measurement instrument; and
a first voltage detection circuit configured to detect a first contact check voltage across the first force node and first sense node;
a second contact check circuit, including:
a second contact check current source coupled between a second force node and a second sense node of the test and measurement instrument, the second contact check current source being galvanically isolated from the one or more power supplies in the test and measurement instrument; and
a second voltage detection circuit configured to detect a second contact check voltage across the second force node and second sense node;
a first electrical connection path including a first electrical connection between the first force node and a first contact node of a device under test and a second electrical connection between the first sense node and the first contact node;
a second electrical connection path including a first electrical connection between the second force node and a second contact node of the device under test and a second electrical connection between the second sense node and the second contact node; and
a controller coupled to the first and second contact check circuits, the controller configured to control the first and second contact check current sources to supply the first and second contact check currents to the first and second electrical connection paths and, based on the first and second contact check currents and first and second contact check voltages detected by the first and second voltage detection circuits, the controller configured to determine first and second contact resistances of the first and second electrical connection paths and to detect faults in the first and second electrical connection paths based on the determined first and second contact resistances.

20. The test and measurement instrument of claim 19, wherein the test and measurement instrument is a source measure unit (SMU).
